(19) United States
(12) Patent Application Publication
(10) Pub. No.: US 2025/0261564 A1
(43) Pub. Date: Aug. 14, 2025

(54) MANUFACTURING PROCESS TO ENABLE MAGNTIC TOPLOGICAL IN-MEMORY COMPUTING AI DEVICES

(71) Applicant: Aurora Micro Devices LLC, Emerald Hills, CA (US)

(72) Inventors: Kuok San Ho, Mountain Ranch, CA (US); Ming Jiang, San Jose, CA (US)

(73) Assignee: Aurora Micro Devices LLC, Emerald Hills, CA (US)

(21) Appl. No.: 18/438,445

(22) Filed: Feb. 10, 2024

(51) Int. Cl. H10N 50/01; H01F 10/32; H10B 61/00; H10N 50/10; H10N 50/85

(52) U.S. Cl. CPC H10N 50/01; H01F 10/3254; H10B 61/00; H10N 50/10; H10N 50/85

(57) ABSTRACT

An apparatus and a fabricating method therefor of magnetic in-memory computing device for AI inference that comprises a spin orbit torque (SOT) cell configured from seed layer and SOT Topological layer, wherein the SOT Topological layer includes but not limited to a Topological half Heusler alloy (THHA) or a Topological insulator (TI) or a mixture of THHA and TI layer; a magnetic tunnel junction (MTJ) cell configured from tunneling magnetoresistance (TMR) stack; and a fabricating method providing a SOT-MTJ cell configured with adjustable free layer length and slope angle between MTJ free layer and SOT THHA layer. The SOT THHA layer and the MTJ free layer are configured to generate memory writing; the MTJ TMR is configured to provide memory reading; and together a magnetic chip comprising the SOT-MTJ cells configuring a non-volatile memory array to store corresponding programmable weight matrix provides Al in-memory computing for edge applications.

### CROSS REFERENCE TO RELATED APPLICATIONS

Not Applicable.

### STATEMENT RE: FEDERALLY SPONSORED RESEARCH/DEVELOPMENT

Not Applicable.

### BACKGROUND OF THE DISCLOSURE

### Field of the Disclosure

Embodiments of the present disclosure generally relate to a magnetic in-memory computing AI device utilizing SOT THHA layer and a method of manufacturing processes and materials therefor.

### Description of the Related Art

Topological insulator (TI) has been proposed for magnetoresistive random access memory utilizing spin orbit torque (SOT) effect. However, TIs have low melting temperature and prone to corrosion during device fabrication. More importantly, the tight manufacturing requirement of memory array has limited a wide range of TI processes and materials being deployed due to reliability and defects concerns.

Therefore, to enable the Topological SOT magnetic memory device providing AI in-memory computing, there is a need for an improved manufacturing process for an improved SOT device utilizing TI materials and a deployment of Topological half Heusler alloy (THHA) material to reduce the defect rate significantly, improve the performance and reliability of memory array and its high temperature performance, which are especially important in high volume manufacture and will significantly reduce the total cost of AI devices.

### SUMMARY OF THE DISCLOSURES

The present disclosure generally relates to manufacturing processes and materials to enable a Topological SOT magnetic device for deploying in-memory computing for AI inference optimized for edge applications. The device and a fabricating method therefor of in-memory computing AI device comprising a spin orbit torque (SOT) cell configured from seed layer and SOT Topological layer, wherein the SOT Topological layer includes but not limited to a Topological half Heusler alloy (THHA) or a Topological insulator (TI) or a mixture of THHA and TI layer; a magnetic tunnel junction (MTJ) cell configured from tunneling magnetoresistance (TMR) stack of seed layer/free layer/MgO/pin layer2/Ru/pin layer1/AFM/cap layer; and a fabricating method therefor comprising manufacturable processes and materials providing a SOT-MTJ cell configured with adjustable free layer length and slope angle between MTJ free layer and SOT THHA layer, wherein the SOT THHA layer and the MTJ free layer are configured to generate memory writing; the MTJ TMR is configured to provide memory reading; and together a magnetic chip comprising SOT-MTJ cells configuring a non-volatile memory array to store a corresponding programmable weight matrix provides Al in-memory computing.

In one embodiment, a method for fabricating SOT-MTJ cell configuring a corresponding magnetic in-memory computing AI device comprising: providing a SOT layer including seed layer deposition, Topological layer full film deposition, patterning through lithography and Ion Mill, dielectric film refill, and CMP; providing MTJ patterning step 1 including partial mill with Low Angle Ion Mill and End Point to vertical mill through and stop after a MgO film removal; providing MTJ patterning step 2 including partial mill with High Angle Ion Mill and End Point to shadow mill through and stop after a free layer and seed layer removal, wherein free layer (FL) length and slope angle between MTJ free layer and SOT Topological layer are adjustable by Ion Mill angle and hard mask height to improve SOT device reliability and defects; providing a dielectric material refill, CMP with CMP Stop Layer, and Ion Mill with End Point to final cap surface.

In another embodiment, each corresponding SOT cell in the device comprises the Topological layer of an exemplary embodiment comprising Topological Half Heusler Alloy (THHA) APtBi, wherein A comprises Y, Lu; each corresponding SOT cell in the device comprises Topological layer of another exemplary embodiment comprising Topological Half Heusler Alloy (THHA) BPdBi, wherein B comprises Y, Sm, Gd, Tb, Dy, Ho, Er, Tm, Lu; each corresponding SOT cell in the device comprises Topological layer of yet another exemplary embodiment comprising Topological Insulator (TI) bismuth antimony BiSb and its compound CBiSb, wherein C comprises Ni. Each corresponding SOT cell in the device comprises a Topological layer comprising epitaxial structure and crystalline orientation promoted from underneath seed layer comprising Ta, Cr, Ru, Zr, Al, Ni, Co, Hf, MgO, or combinations thereof.

In yet another embodiment, each corresponding MTJ cell in the device comprises tunneling magnetoresistance (TMR) stack of seed layer/free layer/MgO/pin layer2/Ru/pin layer1/AFM/cap layer comprising AFM comprises PtMn, IrMn, FeMn, CoPt; pin layer PL1/pin layer PL2 comprises CoFeB, CoFe/NiFe, Ta, CoHf; Ru thickness comprises 2-10A; free layer FL comprises CoFeB, CoFe/NiFe, Ta, CoHf; MgO comprises crystalline orientation (001), thickness 2-40A, and device resistant 100-1000 Ohm. Each corresponding MTJ cell further comprises the cap and seed layers as breaking/blocking layer (BL) to promote texture, block diffusion, and improve TMR ratio and Topological layer Hall effect comprising Ta, Ru, Zr, Al, Ni, Co, Hf, HfO2, MgO or combinations thereof. Each corresponding SOT-MTJ cell comprises 3 terminals: the writing is done by applied current between T1 and T2, to switch MTJ TMR FL the parallel and antiparallel states (referred to PL) by the SOT Topological layer; the reading is done by the TMR between T1 and T3; and the T1, T2, and T3 terminals are metal lines comprising Al, Cu, and W.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic cross-sectional view of certain embodiments of a Topological insulator (TI) spin-orbit torque (SOT) device from Prior Art.

FIG. 2 is a schematic illustration of cross-sectional view of a magnetic Topological half Heusler alloy (THHA) SOT-MTJ in-memory computing AI device fabricated from manufacturable processes and materials according to various embodiments.

FIG. 3 is a schematic illustration of cross-sectional view of an exemplary embodiment of a process flow of fabricating STO-TMJ AI device providing SOT seed layer and Topological layer full film deposition, patterning through lithography and Ion Mill, dielectric material refill, and CMP.

FIG. 4 is a schematic illustration of a cross-sectional view of an exemplary embodiment of a process flow of fabricating STO-TMJ AI device providing TMR full film deposition, hard mask (HM) patterning through lithography and RIE.

FIG. 5 is a schematic illustration of cross-sectional view of an exemplary embodiment of a process flow of fabricating STO-TMJ AI device providing MTJ partial mill step 1 low angle Ion Mill with end point.

FIG. 6 is a schematic illustration of cross-sectional view of an exemplary embodiment of a process flow of fabricating STO-TMJ AI device providing MTJ partial mill step2 high angle Ion Mill with end point-FL length adjustable by Ion Mill angle and hard mask height.

FIG. 7 is a schematic illustration of cross-sectional view of an exemplary embodiment of a process flow of fabricating STO-TMJ AI device providing dielectric material refill, CMP with CMP stop layer+RIE/Ion Mill with end point.

FIG. 8 is a schematic illustration of a cross-sectional view of an exemplary embodiment of a process flow of fabricating STO-TMJ AI device providing metal line.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In the following, reference is made of embodiments of the disclosure. However, it should be understood that the disclosure is not limited to specific described embodiments. Instead, any combination of the following features and elements, whether related to different embodiments or not, is contemplated to implement and practice the disclosure. Furthermore, although embodiments of the disclosure may achieve advantages over other possible solutions and/or over the prior art, whether or not a particular advantage is achieved by a given embodiment is not limiting of the disclosure. Thus, the following aspects, features, embodiments and advantages are merely illustrative and are not considered elements or limitations of the appended claims except where explicitly recited in a claim(s). Likewise, reference to “the disclosure” shall not be construed as a generalization of any inventive subject matter disclosed herein and shall not be considered to be an element or limitation of the appended claims except where explicitly recited in a claim(s).

The present disclosure generally relates to manufacturing processes and materials to enable a Topological half Heusler alloy (THHA) SOT magnetic device providing Al in-memory computing.

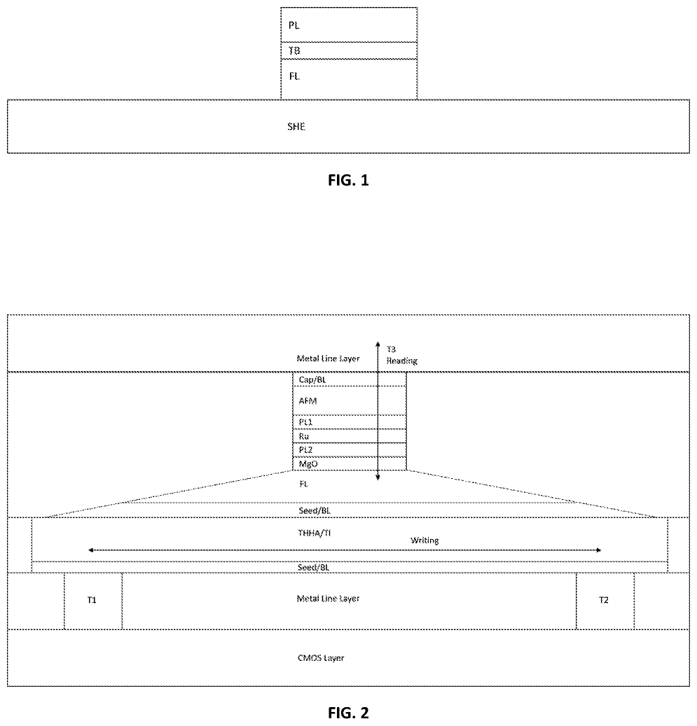

FIG. 1 is a schematic cross-sectional view of certain embodiments of a Topological insulator (TI) spin orbit torque (SOT) device from Prior Art. However, TIs have low melting temperature and prone to corrosion during device fabrication. More importantly, the tight manufacturing requirement of memory array has limited a wide range of TI processes and materials being deployed due to reliability and defects concerns.

Therefore, to enable the Topological SOT magnetic memory device providing AI in-memory computing, there is a need for an improved manufacturing process for an improved SOT device utilizing TI materials and a deployment of Topological half Heusler alloy (THHA) material to reduce the defect rate significantly, improve the performance and reliability of memory array and its high temperature performance.

FIG. 2 is a schematic illustration of cross-sectional view of a magnetic Topological half Heusler alloy (THHA) SOT-MTJ in-memory computing AI device fabricated from manufacturable processes and materials according to various embodiments. The device and a fabricating method of in-memory computing AI device comprising a magnetic array cell comprising spin orbit torque (SOT) cell configured from seed layer and THHA layer; magnetic tunnel junction (MTJ) cell configured from tunneling magnetoresistance (TMR) stack of seed layer/free layer/MgO/pin layer2/Ru/pin layer1/AFM/cap layer; and a fabricating method therefor comprising manufacturable processes and materials providing a SOT-MTJ cell configured with adjustable free layer length and slope angle between MTJ free layer and SOT THHA layer, wherein the SOT THHA layer and MTJ free layer are configured to generate memory writing; the MTJ TMR is configured to provide memory reading; and together a magnetic chip comprising SOT-MTJ cells configuring a non-volatile memory array to store a corresponding programmable weight matrix provides Al in-memory computing.

Each corresponding SOT-MTJ cell comprises 3 terminals: the writing is done by applied current between T1 and T2, to switch MTJ TMR FL the parallel and antiparallel states (referred to PL) by the SOT THHA layer; the reading is done by the TMR between T1 and T3; and the T1, T2, and T3 terminals are metal lines comprising Al, Cu, and W.

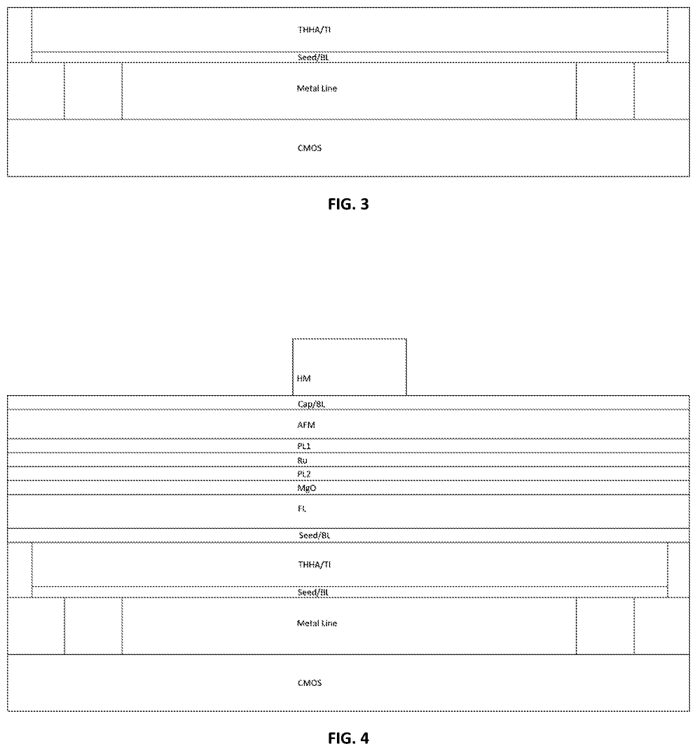

FIG. 3 is a schematic illustration of cross-sectional view of an exemplary embodiment of a process flow of fabricating STO-TMJ AI device providing SOT seed layer and Topological layer full film deposition, patterning through lithography and Ion Mill, dielectric material refill, and CMP.

In one exemplary embodiment, each corresponding SOT cell in the device comprises the Topological layer of comprising Topological Half Heusler Alloy (THHA) APtBi, wherein A comprises Y, Lu.

In another exemplary embodiment, each corresponding SOT cell in the device comprises Topological layer comprising Topological Half Heusler Alloy (THHA) BPdBi, wherein B comprises Y, Sm, Gd, Tb, Dy, Ho, Er, Tm, Lu.

In another exemplary embodiment, each corresponding SOT cell in the device comprises a Topological layer of yet another exemplary embodiment comprising Topological Insulator (TI) bismuth antimony BiSb and its compound CBiSb, wherein C comprises Ni.

In another exemplary embodiment, each corresponding SOT cell comprises the Topological layer of another exemplary embodiment further comprising a mixture among APtBi, BPdBi, or CBiSb.

In yet another exemplary embodiment, each corresponding SOT cell in the device comprises Topological layer comprising epitaxial structure and crystalline orientation promoted from underneath seed layer comprising Ta, Cr, Ru, Zr, Al, Ni, Co, Hf, MgO, or combinations thereof.

FIG. 4 is a schematic illustration of a cross-sectional view of an exemplary embodiment of a process flow of fabricating STO-TMJ AI device providing TMR full film deposition, hard mask (HM) patterning through lithography and RIE.

In yet another embodiment, each corresponding MTJ cell in the device comprises tunneling magnetoresistance (TMR) stack of seed layer/free layer/MgO/pin layer2/Ru/pin layer1/AFM/cap layer comprising AFM comprises PtMn, IrMn, FeMn, CoPt; pin layer PL1/pin layer PL2 comprises CoFeB, CoFe/NiFe, Ta, CoHf; Ru thickness comprises 2-10A; free layer FL comprises CoFeB, CoFe/NiFe, Ta, CoHf; MgO comprises crystalline orientation (001), thickness 2-40A, and device resistant 100-1000 Ohm. Each corresponding MTJ cell further comprises the cap and seed layers as breaking/blocking layer (BL) to promote texture, block diffusion, and improve TMR ratio and Topological layer Hall effect comprising Ta, Ru, Zr, Al, Ni, Co, Hf, HfO2, MgO or combinations thereof.

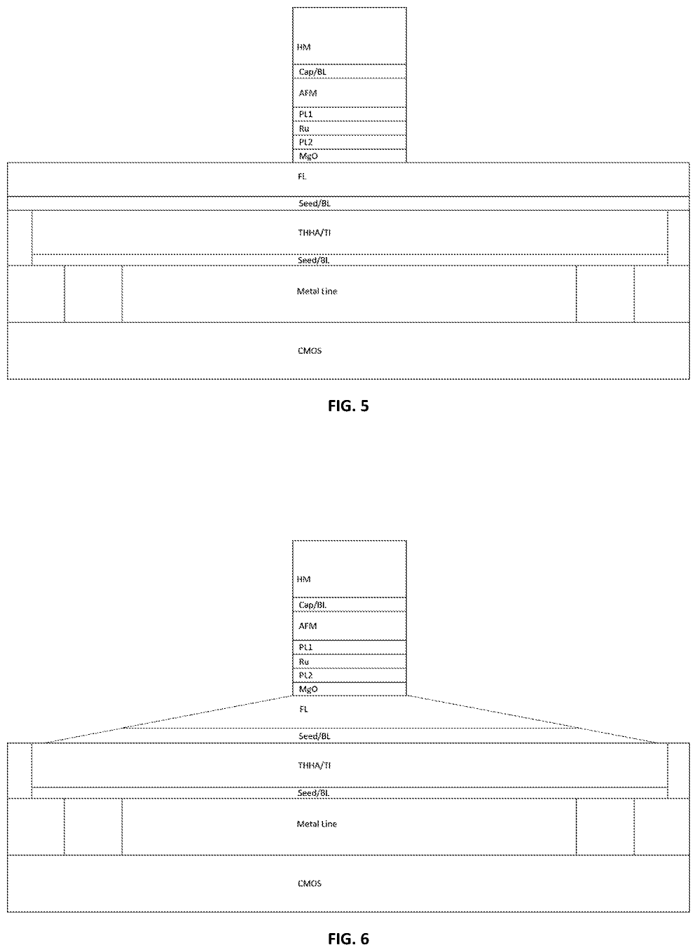

FIG. 5 is a schematic illustration of cross-sectional view of an exemplary embodiment of a process flow of fabricating STO-TMJ AI device providing MTJ partial mill step 1 low angle Ion Mill with end point.

FIG. 6 is a schematic illustration of cross-sectional view of an exemplary embodiment of a process flow of fabricating STO-TMJ AI device providing MTJ partial mill step2 high angle Ion Mill with end point.

In one exemplary embodiment, each corresponding MTJ patterning Ion Mill comprises providing a MTJ patterning step 1 including partial mill with low angle Ion Mill and end point to vertical mill through and stop after a MgO film removal; and then providing a MTJ patterning step 2 including partial mill with high angle Ion Mill and end point to shadow mill through and stop after a free layer and seed layer removal, wherein free layer (FL) length and slope angle between MTJ free layer and SOT Topological layer are adjustable by Ion Mill angle and hard mask height.

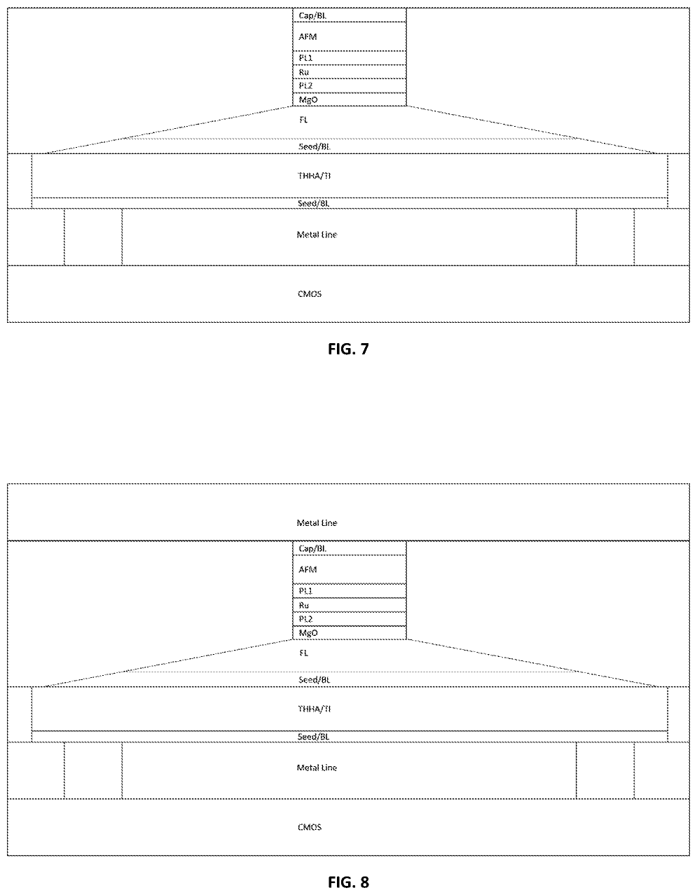

FIG. 7 is a schematic illustration of cross-sectional view of an exemplary embodiment of a process flow of fabricating STO-TMJ AI device providing dielectric material refill, CMP with CMP stop layer and RIE/Ion Mill with end point.

FIG. 8 is a schematic illustration of a cross-sectional view of an exemplary embodiment of a process flow of fabricating STO-TMJ AI device providing metal line.

While the foregoing is directed to embodiments of the present disclosure, other and further embodiments of the disclosure may be devised without departing from the basic scope thereof, and the scope thereof is determined by the claims that follow.

The invention claimed is:

1. An apparatus and a fabricating method therefor of magnetic in-memory computing device for artificial intelligent (AI) inference that comprises:
(a) a spin orbit torque (SOT) cell configured from a seed layer and a Topological layer;
(b) a magnetic tunnel junction (MTJ) cell configured from a tunneling magnetoresistance (TMR) stack of seed layer/free layer/MgO/pin layer2/Ru/pin layer1/AFM/cap layer;
(c) a fabricating method therefor comprising materials and manufacturable processes providing a SOT-MTJ cell configured with adjustable free layer length and slope angle between the MTJ free layer and the SOT Topological layer,
wherein:
(d) the SOT Topological layer and the MTJ free layer are configured to generate memory writing;
(e) the MTJ TMR is configured to provide memory reading;
(f) and together a magnetic chip comprising the SOT-MTJ cells configuring a non-volatile memory array to store a corresponding programmable weight matrix provides Al in-memory computing.

2. A method of claim 1 for fabricating the SOT-MTJ cell configuring a corresponding magnetic in-memory computing device, comprising:
(a) providing Topological SOT layer including seed layer deposition, Topological layer full film deposition, patterning through lithography and Ion Mill, dielectric film refill, and CMP;
(b) providing MTJ TMR full film stack and hard mask including TMR full film deposition, hard mask patterning through lithography and RIE;
(c) providing MTJ patterning Ion Mill;
(d) providing dielectric material refill, CMP with CMP Stop Layer, and Ion Mill with End Point to final cap surface.

3. A method of claim 2, wherein each corresponding MTJ patterning Ion Mill further comprises:
(a) providing a MTJ patterning step 1 including partial mill with low angle Ion Mill and end point to vertical mill through and stop after a MgO film removal;
(b) providing a MTJ patterning step 2 including partial mill with high angle Ion Mill and end point to shadow mill through and stop after a free layer and seed layer removal, wherein free layer (FL) length and slope angle between the MTJ free layer and the SOT Topological layer are adjustable by Ion Mill angle and hard mask height.

4. The apparatus of claim 1, wherein each corresponding SOT cell comprises the Topological layer of an exemplary embodiment comprising Topological Half Heusler Alloy (THHA) APtBi, wherein A comprises Y, Lu.

5. The apparatus of claim 1, wherein each corresponding SOT cell comprises the Topological layer of another exemplary embodiment comprising Topological Half Heusler Alloy (THHA) BPdBi, wherein B comprises Y, Sm, Gd, Tb, Dy, Ho, Er, Tm, Lu.

6. The apparatus of claim 1, wherein each corresponding SOT cell comprises the Topological layer of yet another exemplary embodiment comprising Topological Insulator (TI) bismuth antimony BiSb and its compound CbiSb wherein C comprises Ni, or a mixture among APtBi, BPdBi, and CBiSb.

7. The apparatus of claim 1, wherein each corresponding SOT cell comprises the Topological layer further comprising epitaxial structure and crystalline orientation promoted from the underneath the seed layer comprising Ta, Cr, Ru, Zr, Al, Ni, Co, Hf, MgO, or combinations thereof.

8. The apparatus of claim 1, wherein each corresponding MTJ cell comprises the tunneling magnetoresistance (TMR) stack of seed layer/free layer/MgO/pin layer2/Ru/pin layer1/AFM/cap layer comprising:
(a) AFM comprises PtMn, IrMn, FeMn, CoPt, or combinations thereof;
(b) pin layer PL1/pin layer PL2 comprises CoFeB, CoFe/NiFe, Ta, CoHf, or combinations thereof;
(c) Ru thickness comprises 2-10A;
(d) free layer FL comprises CoFeB, CoFe/NiFe, Ta, CoHf, or combinations thereof;
(e) MgO comprises crystalline orientation (001), thickness 2-40A, and device resistant 100-1000 Ohm.

9. The apparatus of claim 9, wherein each corresponding MTJ cell further comprises the cap and seed layers as breaking/blocking layer (BL) to promote texture, block diffusion, and improve TMR ratio and Topological layer Hall effect comprising Ta, Ru, Zr, Al, Ni, Co, Hf, HfO2, MgO or combinations thereof.

10. The apparatus of claim 1, wherein each corresponding SOT-MTJ cell comprises 3 terminals:
(a) the writing is done by applied current between T1 and T2, to switch MTJ TMR FL the parallel and antiparallel states (referred to PL) by the SOT Topological layer;
(b) the reading is done by the TMR between T1 and T3;
(c) and the T1, T2, and T3 terminals are metal lines comprising Al, Cu, and W.
